(19) United States
(12) Patent Application Publication
(10) Pub. No.: US 2017/0261866 A1
(43) Pub. Date: Sep. 14, 2017

(54) THERMAL CONDITIONING FLUID PUMP

(71) Applicant: ASML NETHERLANDS B.V., Veldhoven (NL)

(72) Inventor: Theodorus Petrus Maria CADEE, Asten (NL)

(73) Assignee: ASML NETHERLANDS B.V., Veldhoven (NL)

(21) Appl. No.: 15/517,485

(22) PCT Filed: Oct. 5, 2015
(86) PCT No.: PCT/EP2015/072940

§ 371 Date: Apr. 6, 2017

(30) Foreign Application Priority Data
Nov. 5, 2014 (EP) 14191864.9

(51) Int. Cl. G03F 7/20; F28F 13/16; G02B 7/00; F28D 15/02

(52) U.S. Cl. CPC G03F 7/70891; F28D 15/02; F28F 13/16; G02B 7/008; F28F 2250/08

(57) ABSTRACT

A pump includes a collecting duct to guide a two-phase fluid provided with magnetic field responsive particles, a collecting duct magnet system arranged along the collecting duct and configured to generate a magnetic field in at least a part of the collecting duct, a pumping duct to guide the two-phase fluid, a pumping duct inlet being connected to a collecting duct outlet, and a pumping duct magnet system arranged along the pumping duct and configured to generate a magnetic field in at least a part of the pumping duct. A pump driver is configured to drive the collecting duct magnet system to generate a spatial repetition of collecting duct magnetic fields moving along a length of the collecting duct, and is configured to drive the pumping duct magnet system to generate a spatial repetition of pumping duct magnetic fields moving along a length of the pumping duct.

### CROSS-REFERENCE TO RELATED APPLICATIONS

This application claims priority of EP application 14191864.9 which was filed on 5 Nov. 2014 and which is incorporated herein in its entirety by reference.

### FIELD

The present disclosure relates to a pump constructed to pump a thermal conditioning fluid, a thermal conditioning system comprising such pump, a lithographic apparatus comprising such thermal conditioning system and a method of pumping a thermal conditioning fluid.

### RELATED ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

When projecting the pattern onto the substrate, the substrate may be exposed to heat from various sources of heat. For example, an actuator of the support, such as a motor which moves the support e.g. in a scanning movement, may generate heat. Likewise, the energy of the irradiation which interacts with the substrate, may form a source of heat.

Such sources of heat may result in many effects, e.g. a (typically non-uniform) thermal expansion of the substrate, a (typically non-uniform) thermal expansion of the support, etc. These effects may contribute to various errors in the processing of resist-covered substrates by the lithographic apparatus, such as example alignment errors and overlay errors.

In order to counteract these effects, a temperature conditioning is desired so as to keep the substrate at a substantially constant temperature. Thereto, thermal conditioning ducts may be provided in the support.

An example of a thermal conditioning system is provided by a two-phase thermal conditioning system. A temperature conditioning effect may be obtained in that a two-phase fluid transitions from one phase (e.g., liquid phase) to another phase (e.g., gas phase). During a transition from the liquid phase to the gas phase heat is absorbed, whereas during a transition from the gas phase to the liquid phase heat is released. An example of a two-phase fluid is pressurized CO2 (carbon dioxide). A two-phase fluid may require a pump which provides for a circulation of the two-phase fluid, so as to circulate between an area where heat is absorbed and an area where heat is released.

The pump may introduce adverse effects such as vibration.

### SUMMARY

It is desirable to provide an improved temperature conditioning.

In one embodiment, there is provided a pump constructed to pump a thermal conditioning fluid provided with particles responsive to a magnetic field, the pump comprising:

a collecting duct constructed to guide the thermal conditioning fluid from a collecting duct inlet to a collecting duct outlet,

a collecting duct magnet system arranged along the collecting duct and configured for generating a magnetic field in at least a part of the collecting duct,

a pumping duct constructed to guide the thermal conditioning fluid from a pumping duct inlet to a pumping duct outlet, the pumping duct inlet being connected to the collecting duct outlet,

a pumping duct magnet system arranged along the pumping duct and configured for generating a magnetic field in at least a part of the pumping duct, and

a pump driver system configured to drive the collecting duct magnet system to generate a spatial repetition of collecting duct magnetic fields moving from the collecting duct inlet to the collecting duct outlet, the pump driver system further being configured to drive the pumping duct magnet system to generate a spatial repetition of pumping duct magnetic fields moving from the pumping duct inlet to the pumping duct outlet.

In a further embodiment, there is provided a thermal conditioning system comprising the pump according to any of the preceding claims and a thermal conditioning fluid, the thermal conditioning fluid being provided with magnetic field responsive particles.

In a still further embodiment, there is provided a lithographic apparatus comprising a substrate table configured for holding a substrate and a thermal conditioning system according to the invention, the thermal conditioning system being configured for temperature conditioning the substrate table.

In another embodiment, there is provided a lithographic apparatus comprising a projection system for projecting a pattern onto a substrate, the projection system comprising a reflective optical element, the lithographic apparatus further comprising a thermal conditioning system according to the invention, the thermal conditioning system being configured for temperature conditioning the reflective optical element.

In yet another embodiment, there is provided a lithographic apparatus comprising a reference frame, the lithographic apparatus further comprising a thermal conditioning system according to the invention, the thermal conditioning system being configured for thermal conditioning the reference frame.

In still yet another embodiment, there is provided a method of pumping a thermal conditioning fluid provided with particles that are responsive to a magnetic field, the method comprising:

guiding by a collecting duct the thermal conditioning fluid from a collecting duct inlet to a collecting duct outlet of the collecting duct,

guiding by a pumping duct the thermal conditioning fluid from a pumping duct inlet to a pumping duct outlet of the pumping duct, the pumping duct inlet being connected to the collecting duct outlet,

generating a spatial repetition of collecting duct magnetic fields moving from the collecting duct inlet to the collecting duct outlet,

generating a spatial repetition of pumping duct magnetic fields moving from the pumping duct inlet to the pumping duct outlet.

The article “Ferrofluid pump has no moving parts”, dated 26 Sep. 2011, discloses a ferrofluid pump that pumps a fluid comprising nanoscale ferromagnetic particles. (Commissariat, T., “Ferrofluid pump has no moving parts”; PHYSICS WORLD, Sept. 26, 2011 [online], [retrieved Nov. 3, 2014]. Retrieved from the Internet <URL: http://physicsworld.com/cws/article/news/2011/sep/26/ferrofluid-pump-has-no-moving-parts>. Electrical windings are provided around a circumference of a tube to form electrical coils. The coils generate a travelling wave magnetic field. The pump as disclosed in this article does not provide for a collecting duct nor for a collecting of the ferromagnetic particles in order to locally increase a concentration of the ferromagnetic particles prior to providing the fluid to the pumping duct.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1A is a schematic illustration of a reflective lithographic apparatus in which embodiments of the invention may be provided.

FIG. 1B is a schematic illustration of a transmissive lithographic apparatus in which embodiments of the invention may be provided.

FIG. 2 depicts a schematic side view, partly in cross section, of a pump according to an embodiment of the invention.

FIG. 3 depicts an example of a timing sequence of collecting duct magnet drive signals in the pump according to FIG. 2.

FIG. 4 depicts an example of a timing sequence of pumping duct magnet drive signals in the pump according to FIG. 2.

FIG. 5 depicts a highly schematic view of a thermal conditioning system in accordance with an embodiment of the invention.

FIG. 6 depicts a flow diagram of a method of pumping a two-phase fluid in accordance with an embodiment of the invention.

The features and advantages of the present invention will become more apparent from the detailed description set forth below when taken in conjunction with the drawings. Generally, the drawing in which an element first appears is typically indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Before describing such embodiments in more detail, however, it is instructive to present an example environment in which embodiments of the present invention may be implemented.

### Example Reflective and Transmissive Lithographic Systems

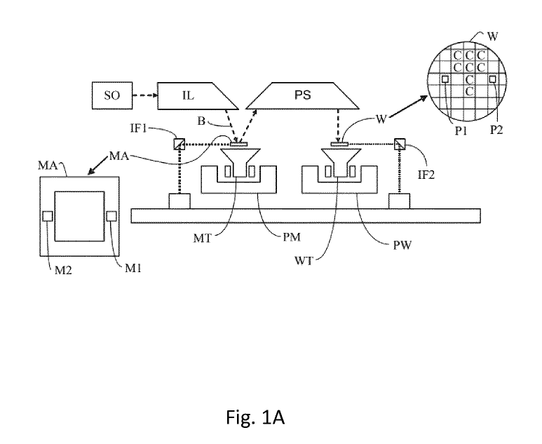

FIGS. 1A and 1B are schematic illustrations of a lithographic apparatus, in which embodiments of the present invention may be implemented. Lithographic apparatus in accordance with FIG. 1A and the lithographic apparatus in accordance with FIG. 1B each include the following: an illumination system (illuminator) IL configured to condition a radiation beam B (for example, DUV or EUV radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. The lithographic apparatuses also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, magnetic, electromagnetic, electrostatic, or other types of optical components, or any combination thereof, for directing, shaping, or controlling the radiation B.

The support structure MT holds the patterning device MA in a manner that depends on the orientation of the patterning device MA, the design of the lithographic apparatuses 100 and 100′, and other conditions, such as whether or not the patterning device MA is held in a vacuum environment. The support structure MT may use mechanical, vacuum, electrostatic, or other clamping techniques to hold the patterning device MA. The support structure MT can be a frame or a table, for example, which can be fixed or movable, as required. The support structure MT can ensure that the patterning device is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C, such as an integrated circuit.

The patterning device MA may be transmissive (as in lithographic apparatus of FIG. 1B) or reflective (as in lithographic apparatus of FIG. 1A). Examples of patterning devices MA include reticles, masks, programmable mirror arrays, and programmable LCD panels. Masks are well known in lithography, and include mask types such as binary, alternating phase shift, and attenuated phase shift, as well as various hybrid mask types. An example of a programmable minor array employs a matrix arrangement of small mirrors, each of which can be individually tilted so as to reflect an incoming radiation beam in different directions. The tilted mirrors impart a pattern in the radiation beam B which is reflected by the mirror matrix.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

The lithographic apparatus in accordance with FIG. 1A and/or lithographic apparatus in accordance with FIG. 1B can be of a type having two (dual stage) or more substrate tables (and/or two or more mask tables) WT. In such “multiple stage” machines, the additional substrate tables WT can be used in parallel, or preparatory steps can be carried out on one or more tables while one or more other substrate tables WT are being used for exposure.

Referring to FIGS. 1A and 1B, the illuminator IL receives a radiation beam from a radiation source SO. The source SO and the lithographic apparatuses can be separate entities, for example, when the source SO is an excimer laser. In such cases, the source SO is not considered to form part of the lithographic apparatuses, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatuses—for example when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In the lithographic apparatus, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil PPU conjugate to an illumination system pupil IPU. Portions of radiation emanate from the intensity distribution at the illumination system pupil IPU and traverse a mask pattern without being affected by diffraction at a mask pattern create an image of the intensity distribution at the illumination system pupil IPU.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatuses 100 and 100′ can be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array of a type as referred to herein.

Combinations and/or variations on the described modes of use or entirely different modes of use can also be employed.

Although specific reference can be made in this text to the use of lithographic apparatus in the manufacture of ICs, it should be understood that the lithographic apparatus described herein can have other applications, such as the manufacture of integrated optical systems, guidance and detection patterns for magnetic domain memories, flat-panel displays, liquid-crystal displays (LCDs), and thin-film magnetic heads. The skilled artisan will appreciate that, in the context of such alternative applications, any use of the terms “wafer” or “die” herein can be considered as synonymous with the more general terms “substrate” or “target portion,” respectively. The substrate referred to herein can be processed, before or after exposure, in for example a track (a tool that typically applies a layer of resist to a substrate and develops the exposed resist), a metrology tool, and/or an inspection tool. Where applicable, the disclosure herein can be applied to such and other substrate processing tools. Further, the substrate can be processed more than once, for example, in order to create a multi-layer IC, so that the term substrate used herein can also refer to a substrate that already contains one or multiple processed layers.

In a further embodiment, lithographic apparatus in accordance with FIG. 1A includes an extreme ultraviolet (EUV) source, which is configured to generate a beam of EUV radiation for EUV lithography. In general, the EUV source is configured in a radiation system (see below), and a corresponding illumination system is configured to condition the EUV radiation beam of the EUV source.

In the embodiments described herein, the terms “lens” and “lens element,” where the context allows, can refer to any one or combination of various types of optical components, including refractive, reflective, magnetic, electromagnetic, and electrostatic optical components.

Further, the terms “radiation” and “beam” used herein encompass all types of electromagnetic radiation, including visible radiation (for example, having a wavelength λ in the range of 400 to 780 nm), ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by air), refers to radiation having a wavelength of approximately 100-200 nm. Deep UV (DUV) generally refers to radiation having wavelengths ranging from 126 nm to 428 nm, and in an embodiment, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

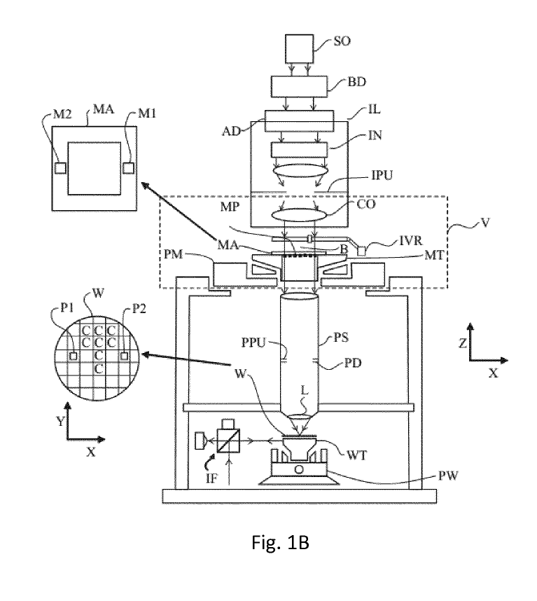

FIG. 2 depicts a schematic view of a pump in accordance with an embodiment of the invention. The pump comprises a collecting duct CDU and a pumping duct PDU. The collecting duct extends from a collecting duct inlet CDI (at a left side as seen in the plane of drawing) to a collecting duct outlet CDO (right side seen in the plane of drawing). The pumping duct extends from a pumping duct inlet PDI to a pumping duct outlet PDU. The pumping duct inlet is connected to the collecting duct outlet. A two-phase fluid, such as CO2 in exchange between a liquid phase and a gas phase, is guided by the collecting duct and the pumping duct. As will be explained in more detail below, the fluid flows from the collecting duct inlet to the collecting duct outlet. As shown in this embodiment, the collecting duct has a width (diameter) which exceeds that of the pumping duct, however in other embodiments the collecting duct and pumping duct may have a same or similar width. The pumping duct and the collecting duct may have any suitable cross sectional shape (i.e. shape in a plane perpendicular to a direction of flow of the fluid), e.g. circular, oval, square, etc. A plurality of collecting duct electromagnets (CDMS) are provided and arranged one behind the other along a length of the collecting duct (the length of the collecting duct extending from the collecting duct inlet to the collecting duct outlet). A plurality of pumping duct electromagnets (PDMS) are provided and arranged one behind the other along a length of the pumping duct (the length of the pumping duct extending from the pumping duct inlet to the pumping duct outlet). The collecting duct electromagnets form a collecting duct magnet system. The pumping duct electromagnets form a pumping duct magnet system. The pump further comprises a pump driver system (PDR), which drives the collecting duct magnet system and the pumping duct magnet system.

The pump driver system drives the collecting duct magnet system to generate a spatial repetition of collecting duct magnetic fields CDMF. The collecting duct magnetic fields CDMF repeat along the length of the collecting duct, in other words, seen along a length of the collecting duct, the collecting duct magnetic field periodically varies. Furthermore, the pump driver system provides that the collecting duct magnetic fields move along a length of the collecting duct, i.e. move from the collecting duct inlet to the collecting duct outlet.

In the exemplary embodiments as described in this document, the fluid that is pumped is a two phase thermal conditioning fluid, i.e. a fluid that is in part in the liquid phase and in part in the gas phase. When heat is absorbed, some of the fluid may transition from liquid phase to gas phase. When heat is released, some of the fluid may transition from gas phase to liquid phase. It will be understood that the pump as described may also be applied to pump any other suitable type of thermal conditioning fluid (e.g. liquid, gas), other than a two phase thermal conditioning fluid.

The fluid to be pumped (such as a two phase fluid) is provided with magnetic field responsive particles, i.e. particles that respond to a magnetic field, such as ferrofluid particles or other particles that respond to a magnetic field, e.g. being magnetizable, exhibiting ferromagnetic properties, etc. The particles may have any suitable size (e.g. particles having a particle size in the order of magnitude of micrometers or nano scale particles) and any suitable number given their purpose as will be explained below. Preferably, the particles remain in suspension in the liquid portion of the two-phase fluid. As the collecting duct magnetic field is intermittent along a length of the collecting duct, the magnetic field responsive particles will—as a result of the intermittent collecting duct magnetic field—move to the regions in the collecting duct where the field is the strongest. As a result, in the collecting duct, the magnetic field responsive particles will locally concentrate.

As the outlet of the collecting duct discharges into the inlet of the pumping duct, the pumping duct will receive the two-phase fluid having local concentrations of magnetic field responsive particles. As a result, at a given point of the pumping duct, e.g. at the inlet of the pumping duct, the concentration of magnetic field responsive particles varies with time, as the concentration increases each time two-phase fluid with collected magnetic field responsive particles passes the inlet of the pumping duct.

The pump driver system further drives the pumping duct magnet system to generate a spatial repetition of pumping duct magnetic fields PDMF moving along a length of the pumping duct, i.e. from the pumping duct inlet to the pumping duct outlet. The pumping duct magnetic fields PDMF repeat along the length of the pumping duct, in other words, seen along a length of the pumping duct, the pumping duct magnetic field periodically varies. Given the high local concentration of magnetic field responsive particles, a pumping duct magnetic field strength that is higher than the magnetic field strength of the collecting duct magnetic field in the collecting duct may be applied locally so as to interact with the collected magnetic field responsive particles, thereby the magnetic field in the propelling duct propelling the two-phase fluid in the area's where the magnetic field responsive particles are concentrated.

The repetition of moving magnetic fields may be generated in a plurality of ways. For example, the pump driver system may move the collection duct magnets along a length of the collecting duct.

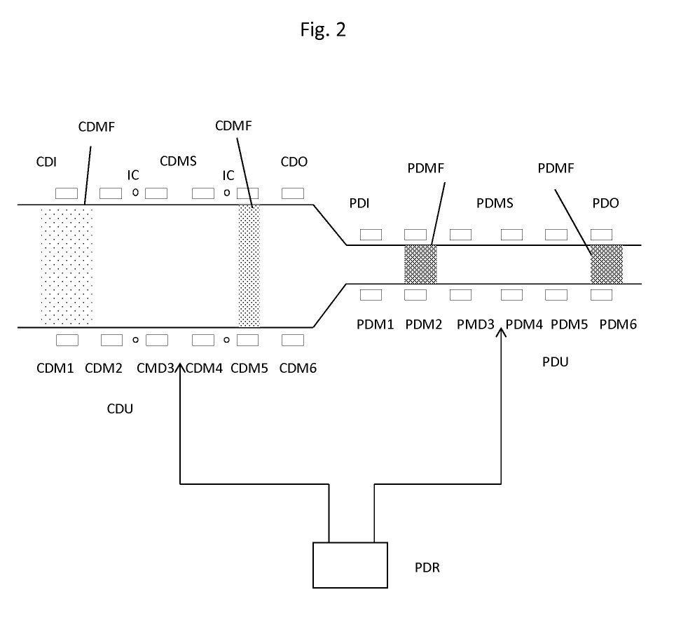

In another embodiment, the collecting duct magnet system comprises a plurality of electromagnets which are consecutively arranged along the length of the collecting duct. The pump driver system may consecutively activate the collecting duct electromagnets, an example of which will be described with reference to FIG. 3.

FIG. 3 depicts a drive of the collecting duct magnets by the pump driver PDR. As illustrated in FIG. 2, the collecting duct magnets CDM1, CDM2 , . . . CDMn which are comprised in the collecting duct magnet system, are arranged one after the other from collecting duct inlet to collecting duct outlet. The collecting duct magnets may for example form (e.g. circular) coils around the collecting duct. A principle of operation will be illustrated based on a driving signal of the collecting duct magnets CDM1-CDM4.

In the exemplary drive scenario as depicted in FIG. 3, first CDM1 is activated by the pump driver system, the drive signal of CDM1 transitioning from 0 to a collecting duct drive level CDM. Then, the drive signal of CDM1 is reduced (in this example reduced to zero) and the drive signal of the following collecting duct magnet CDM2 is increased to the drive level CDM. The same procedure is repeated for CDM3, CDM4, and so on. As a result, a local magnetic field will be generated which in this example starts at CDM1 and over time moves to CDM2, CDM3, CDM4 and so on. Thereby, a collecting of magnetic field responsive particles starts while the magnetic field resides at CDM1. The collected magnetic field responsive particles move over time to the influence region of CDM2, then to the influence region of CDM3, then to the influence region of CDM4. At the same time a concentration of the magnetic field responsive particles tends to increase over time while traveling in the collecting duct, as the collecting effect due to the magnetic field continues. The speed of movement of the magnetic field in the direction from collecting duct inlet to collecting duct outlet may be set by the pump driver system to correspond to a flow speed of the two-phase fluid so as to allow an effective concentration of the magnetic field responsive particles.

The process of activation of the collecting duct magnets CDM1, CDM2, CDM3, CDM4 etc., may be repeated, as depicted in FIG. 3, whereby a next concentration of magnetic field responsive particles is built up in the collecting duct.

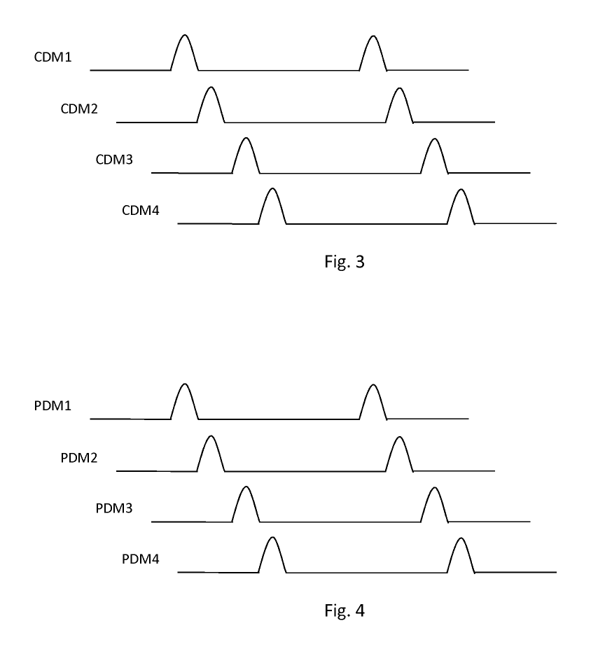

FIG. 4 depicts a drive of the pumping duct magnets by the pump driver system PDR. As illustrated in FIG. 2, the pumping duct magnets PDM1, PDM2, . . . PDMn which are comprised in the pumping duct magnet system, are arranged one after the other from pumping duct inlet to pumping duct outlet. The pumping duct magnets may for example form (e.g. circular) coils around the pumping duct. A principle of operation will be illustrated based on a driving signal of the pumping duct magnets PDM1-PDM4.

In the exemplary drive scenario as depicted in FIG. 4, first PDM1 is activated by the pump driver system, the drive signal of PDM1 transitioning from 0 to a pumping duct drive level PDM. Then, the drive signal of PDM1 is reduced (in this example: reduced to zero) and the drive signal of the following pumping duct magnet PDM2 is increased to the drive level PDM. The same procedure is repeated for PDM3, PDM4, and so on. As a result, a local magnetic field will be generated which in this example starts at PDM1 and over time moves to PDM2, then to PDM3, then to PDM4 and so on. As the magnetic field responsive particles have been collected in the collecting duct so as to provide locally high concentrations of magnetic field responsive particles, a higher magnetic field may be applied in the pumping duct onto the concentrations of magnetic field responsive particles thereby to propel the concentrations of magnetic field responsive particles from the pumping duct inlet to the pumping duct outlet. As a result of the propelling of the concentrated magnetic field responsive particles, the two-phase fluid in which the concentration of magnetic field responsive particles resides, will be propelled from the pumping duct inlet to the pumping duct outlet. The speed of movement of the magnetic field in the direction from pumping duct inlet to pumping duct outlet may be set by the pump driver system in accordance with a desired flow speed of the two-phase fluid. It is noted that, in order to keep a continuous pumping effect, the pump driver system may drive the collecting duct magnets and the pumping duct magnets in a way that a next zone of concentrated magnetic field responsive particles enters or has entered the pumping duct when the previous zone leaves the pumping duct.

As the pumping of the two-phase fluid is provided by a timing sequence of activating the electromagnets of the collecting duct magnet system and the pumping duct magnet system, moving parts may be omitted so that a generation of mechanical vibrations by the pump may be avoided. Furthermore, due to the avoidance of moving parts, wear of the critical parts of the pump may be low. Although FIGS. 3 and 4 depicts excitations in the form of pulses, the excitations may have any suitable form, such as sinusoidal shaped, block shaped, etc.

The larger cross section of the collecting duct as compared to the cross section of the pumping duct provides for a lower flow speed of the two-phase fluid in the collecting duct and a longer time from collecting duct inlet to collecting duct outlet, which tends to promote a concentration of the magnetic field responsive particles as described above. In an embodiment, a cross section may gradually decrease from collecting duct inlet to pumping duct outlet so as to provide a smooth flow transition of the flow of the thermal conditioning fluid.

Generally, it is desired to keep an overall content of magnetic field responsive particles low, as the magnetic field responsive particles may interfere with a thermal conditioning effect of the two-phase fluid: the higher the concentration of magnetic field responsive particles, the lower a density of the two-phase fluid will be. As a result, a thermal conditioning effect that may be obtained by a two-phase fluid having magnetic field responsive particles therein will decrease with an increase in magnetic field responsive particles content.

On the other hand, a maximum pumping power, i.e. a maximum propelling power to be provided by the pump will increase with an increase in the number of magnetic field responsive particles, as a maximum propelling force to be exerted onto the fluid relates to a content of magnetic field responsive particles. A zone of the fluid with a high content pf the magnetic field responsive particles may act as a kind of piston moving in a cylinder. The higher the concentration of magnetic field responsive particles, the more two phase fluid may be propelled therewith while keeping a leakage of two phase fluid between the magnetic field responsive particles at or below a certain level.

The pump in accordance with an embodiment of the invention hence provides a two-stage operation: first, magnetic field responsive particles in the two-phase medium are collected so as to form zones, in which a concentration of the magnetic field responsive particles is high. Then, a magnetic field is applied to propel a respective zone of high concentration magnetic field responsive particles. Due to the concentration of magnetic field responsive particles in the collecting duct, a high propelling force may be applied in the pumping duct by a zone where the concentration is high, which may act as a piston. Thus, on the one hand a high pumping force may be obtained, while on the other hand an overall content of magnetic field responsive particles may be kept low. Thus, the pump in accordance with an embodiment of the invention may tend to enable a combination of a high thermal conditioning effect and a high pumping power.

As depicted in FIG. 2, one or more induction coils IC may be arranged along the collecting duct. The induction coil forms at least one winding that is connected to a corresponding input of the pump driver system. The induction coil will induce an electrical signal in response to a passing of magnetic field responsive particles. Various detection techniques would be possible: for example the magnetic field responsive particles may be magnetized to some extent by the intermittent collecting duct magnetic field, a change in a magnetic flux passing through the induction coil being detected, whereby the flow changes as a result of a change in number of magnetic field responsive particles passing. Alternatively, a current may flow through the induction coil, which current may be affected by a presence of magnetic field response particles Thus, the induction coil will provide a signal to the pump driver input responsive to magnetic field responsive particle concentration and velocity. Due to the collecting effect in the collecting duct, the induction coil will provide a periodic signal to the pump driver—An amplitude of the signal may be indicative of a concentration of magnetic field responsive particles and a frequency, or repetition rate, of the signal may be indicative of flow speed. The pump driver system may be arranged to drive the collecting duct magnet system and the pumping duct magnet system in response to the induction signal as obtained from the at least one induction coil. A field strength of the pumping duct magnetic field and/or the collecting duct magnetic field may be maximized in proportion to an amplitude of the induction signal. A speed of movement of the collecting duct magnetic field and/or the pumping duct magnetic field, i.e. a speed with which the respective field moves along a length of the respective duct as a result of a successive driving of the successive coils of the respective duct, may be set in dependence on, e.g. proportional to, a repetition frequency of the induction signal. This may for example provide that at startup of the pumping process, a drive of the magnet systems may be adapted in accordance with a flow speed and/or particle concentration.

The control by the pump driver system in response to the signal obtained from the at least one induction coil may further be used during start-up of the pump, so as to adapt a driving of the collecting duct magnet system and the pumping duct magnet system to an initially lower concentration of the (initially randomly distributed) magnetic field responsive particles in the two-phase fluid.

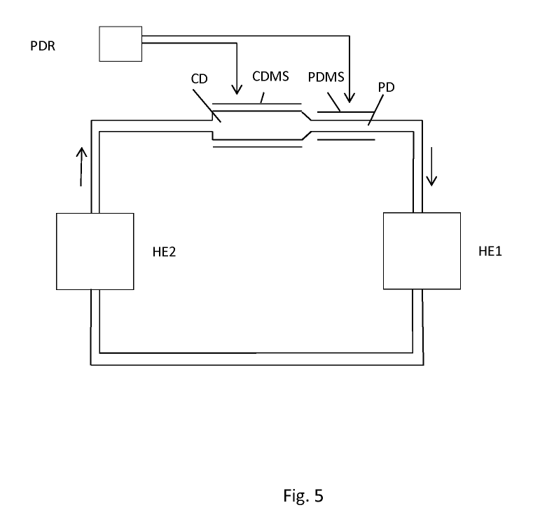

FIG. 5 depicts a thermal conditioning system in accordance with an embodiment of the invention. The thermal conditioning system comprises a pump as described with reference to FIGS. 2-4 and comprising a collecting duct CD, a pumping duct PD, collecting duct magnet system CDMS, pumping duct magnet system PDMS and pump driver PDR having the functions as described above.

The thermal conditioning system further comprises a first heat exchanger HE1 and a second heat exchanger HE2. The two-phase fluid discharges from the pump, via a duct, into the first heat exchanger HE1, which discharges, via a duct into the second heat exchanger HE2. The second heat exchanger in turn discharges into the collecting duct of the pump. The two-phase fluid hence circulates in the two-phase thermal conditioning system from the pump via the first heat exchanger and the second heat exchanger back to the pump. In the first heat exchanger, the two-phase fluid absorbs heat, thereby (in part) changing from liquid phase to gas phase. In the second heat exchanger, the fluid releases heat, thereby in part transferring from the gas phase back to the liquid phase. Particularly during the transition from liquid phase to gas phase, the magnetic field responsive particles that have been grouped together by the pump will more randomly distribute themselves in the two-phase fluid, and hence will be regrouped again in the collecting duct. The first and second heat exchanger may have any suitable construction, such as a meander, spiral shape, etc. Although FIG. 5 depicts a single pump, it will be understood that a plurality of pumps may be provided in the thermal conditioning system, for example one upstream of the first heat exchanger HE1 and one upstream of the second heat exchanger HE2. Also, parallel ducts may be provided, each being provided with a respective pump.

A lithographic apparatus may be provided with the thermal conditioning system (i.e. with the pump) according to the invention. For example, a support or substrate table of the lithographic apparatus, the support or substrate table being configured to hold the substrate, may be provided with the thermal conditioning system according to the invention. For example, a closed system such as the thermal conditioning system as depicted in FIG. 5, may be provided in the substrate table, in order to condition (cool or heat as required) a temperature of the substrate. As the pump according to the invention operates without moving parts, a generation of vibrations may be omitted, which may enable to provide the thermal conditioning system, including the pump and heat exchanger, in the substrate table. A lithographic apparatus, such as the lithographic apparatus explained with reference to FIGS. 1A and 1B, may be provided with such a thermal conditioning system according to the invention.

As another example, in a lithographic apparatus of a reflective type, such as described with reference to FIG. 1A, a thermal conditioning system in according with the invention may be provided to temperature condition a reflective optical element (such as a reflective mirror) of the projection system PS of such lithographic apparatus. As the pump according to the invention operates without moving parts, a generation of vibrations may be omitted, which may enable to provide the thermal conditioning system, including the pump and heat exchanger, in the reflective optical element. The thermal conditioning system may be applied to thermally condition the reflective optical element and may be arranged behind a reflective surface thereof. For example, the ducts of the thermal conditioning system may branch into plural thermal conditioning ducts which extend in the reflective element along the reflective surface thereof.

The pump of a thermal cooling system according to the invention may also be used for thermally conditioning, e.g., cooling, the metrology frame of a lithographic apparatus. In operational use of a lithographic apparatus, the precise location of the substrate to be exposed needs to be known with respect to the projection system that projects the image of the mask on a target portion of the substrate. The optical system has a specific position with respect to a reference frame (or: metrology frame), and the substrate is supported by a substrate stage that is moveable relative to this reference frame. Accordingly, the relative position of the substrate stage with respect to the reference frame co-determines the location of the substrate with respect to the projection system. The relative position of the substrate stage with respect to the reference frame is typically determined via encoders that interact optically with grid plates. The grid plates are accommodated at the reference frame and the encoders at the substrate stage. Alternatively, the grid plates are accommodated at the reference frame, and the encoders are accommodated at the substrate stage. A thermal load on the reference frame induces a (local) thermal expansion of the reference frame that may affect the accuracy of the position of the substrate stage as determined via the interaction between grid plates and encoders. Likewise, a (varying) mechanical load on the reference frame may affect the accuracy of the position of the substrate stage as determined via the interaction between grid plates and encoders. Thermally conditioning the reference frame by means of the pump according to the invention is thermodynamically highly effective and highly attractive from the mechanical point of view owing to the absence of vibrations. An example of a reference frame is depicted in FIG. 1B, where the projection system PS and the wafer table (support) WT are positioned with respect to the reference frame and a position of the wafer table WT is measured with respect to the reference frame.

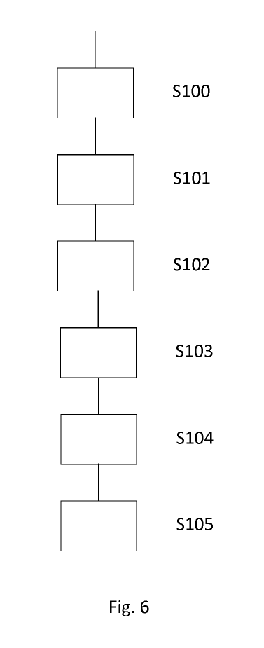

FIG. 6 depicts a flow diagram of a method of pumping a two-phase fluid in a two-phase thermal conditioning system, according to an embodiment of the invention. The method comprises guiding by a collecting duct the two-phase fluid from a collecting duct inlet to a collecting duct outlet of the collecting duct (step S100), generating a magnetic field in at least part of the collecting duct by a collecting duct magnet system arranged along the collecting duct (step S101), guiding by a pumping duct the two-phase fluid from a pumping duct inlet to a pumping duct outlet, the pumping duct inlet being connected to the collecting duct outlet (step S102), generating a magnetic field in at least part of the pumping duct by a pumping duct magnet system arranged along the pumping duct (step S103), driving the collecting duct magnet system to generate a spatial repetition of collecting duct magnetic fields moving along a length of the collecting duct (step S104), driving the pumping duct magnet system to generate a spatial repetition of pumping duct magnetic fields moving along a length of the pumping duct (step S105), wherein a magnetic field strength of the pumping duct magnetic field may exceed a magnetic field strength of the collecting duct magnetic fields.

The descriptions above are intended to be illustrative, not limiting. Thus, it will be apparent to one skilled in the art that modifications may be made to the present invention as described without departing from the scope of the claims set out below. The pump according to the invention may be used for thermal conditioning of an object, be it heating the object or cooling the object. Especially with regard to lithographic apparatus, it is remarked here that the pump according to the invention is attractive as a component of a thermal conditioning system: vibrations and wear are largely absent, and the thermal conditioning by means of a two-phase fluid is highly effective.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A pump constructed to pump a thermal conditioning fluid provided with particles responsive to a magnetic field, the pump comprising:
a collecting duct constructed to guide the thermal conditioning fluid from a collecting duct inlet to a collecting duct outlet,
a collecting duct magnet system arranged along the collecting duct and configured to generate a magnetic field in at least a part of the collecting duct,
a pumping duct constructed to guide the thermal conditioning fluid from a pumping duct inlet to a pumping duct outlet, the pumping duct inlet being connected to the collecting duct outlet,
a pumping duct magnet system arranged along the pumping duct and configured to generate a magnetic field in at least a part of the pumping duct, and
a pump driver system configured to drive the collecting duct magnet system to generate a spatial repetition of collecting duct magnetic fields moving from the collecting duct inlet to the collecting duct outlet, and configured to drive the pumping duct magnet system to generate a spatial repetition of pumping duct magnetic fields moving from the pumping duct inlet to the pumping duct outlet.

2. The pump according to claim 1, wherein a diameter of the collecting duct exceeds a diameter of the pumping duct.

3. The pump according to claim 1, wherein a magnetic field strength of the pumping duct magnetic field exceeds a magnetic field strength of the collecting duct magnetic field.

4. The pump according to claim 1, wherein the collecting duct magnet system comprises at least one induction coil configured to generate an induction signal, the at least one induction coil being connected to a signaling input of the pump driver system to receive the induction signal, the pump driver system being configured to drive the collecting duct magnet system and the pumping duct magnet system in synchronism with the induction signal.

5. The pump according to claim 1, wherein the collecting duct magnet system comprises a plurality of collecting duct electromagnets arranged along the length of the collecting duct from the collecting duct inlet to the collecting duct outlet,
wherein the pumping duct magnet system comprises a plurality of pumping duct electromagnets arranged along the length of the pumping duct from the pumping duct inlet to the pumping duct outlet, and
wherein the pump driver is configured to drive the collecting duct electromagnets to generate the spatial repetition of collecting duct magnetic fields moving from the collecting duct inlet to the collecting duct outlet and to drive the pumping duct electromagnets to generate the spatial repetition of pumping duct magnetic fields moving from the pumping duct inlet to the pumping duct outlet.

6. A thermal conditioning system comprising the pump according to claim 1 and a thermal conditioning fluid, the thermal conditioning fluid being provided with particles responsive to a magnetic field.

7. A lithographic apparatus comprising a substrate table configured to hold a substrate and the thermal conditioning system according to claim 6, the thermal conditioning system configured to thermally condition the substrate table.

8. A lithographic apparatus comprising a projection system configured to project a pattern onto a substrate, the projection system comprising a reflective optical element, the lithographic apparatus further comprising the thermal conditioning system according to claim 6, the thermal conditioning system configured to thermally condition the reflective optical element.

9. A lithographic apparatus comprising a reference frame, the lithographic apparatus further comprising the thermal conditioning system according to claim 6, the thermal conditioning system configured to thermally condition the reference frame.

10. A method of pumping a thermal conditioning fluid provided with particles that are responsive to a magnetic field, the method comprising:
guiding by a collecting duct the thermal conditioning fluid from a collecting duct inlet to a collecting duct outlet of the collecting duct,
guiding by a pumping duct the thermal conditioning fluid from a pumping duct inlet to a pumping duct outlet of the pumping duct, the pumping duct inlet being connected to the collecting duct outlet,
generating a spatial repetition of collecting duct magnetic fields moving from the collecting duct inlet to the collecting duct outlet, and
generating a spatial repetition of pumping duct magnetic fields moving from the pumping duct inlet to the pumping duct outlet.

11. The method according to claim 10, wherein a diameter of the collecting duct exceeds a diameter of the pumping duct.

12. The method according to claim 10, wherein a magnetic field strength of the pumping duct magnetic fields exceeds a magnetic field strength of the collecting duct magnetic fields.

13. The method according to claim 10, further comprising using at least one induction coil to generate an induction signal and driving a collecting duct magnet system that generates the collecting duct magnetic fields and a pumping duct magnet system that generates the pumping duct magnetic fields, in synchronism with the induction signal.

14. The method according to claim 10, wherein a plurality of collecting duct electromagnets are arranged along the length of the collecting duct from the collecting duct inlet to the collecting duct outlet and a plurality of pumping duct electromagnets are arranged along the length of the pumping duct from the pumping duct inlet to the pumping duct outlet, and
wherein generating the spatial repetition of collecting duct magnetic fields comprises driving the collecting duct electromagnets to generate the spatial repetition of collecting duct magnetic fields moving from the collecting duct inlet to the collecting duct outlet, and
wherein generating the spatial repetition of pumping duct magnetic fields comprises driving the pumping duct electromagnets to generate the spatial repetition of pumping duct magnetic fields moving from the pumping duct inlet to the pumping duct outlet.

15. The method according to claim 10, comprising thermally conditioning a substrate table of a lithographic apparatus using the thermal conditioning fluid, the substrate table configured to hold a substrate.

16. The method according to claim 10, comprising thermally conditioning a reflective optical element of a projection system of a lithographic apparatus using the thermal conditioning fluid, the projection system configured to project a pattern onto a substrate.

17. The method according to claim 10, comprising thermally conditioning a reference frame of a lithographic apparatus using the thermal conditioning fluid.

18. A lithographic apparatus, comprising:
a projection system configured to project radiation onto a substrate; and
a pump constructed to pump a thermal conditioning fluid provided with particles responsive to a magnetic field through a part of the lithographic apparatus, the pump comprising:
a collecting duct constructed to guide the thermal conditioning fluid from a collecting duct inlet to a collecting duct outlet,
a collecting duct magnet system arranged along the collecting duct and configured to generate a magnetic field in at least a part of the collecting duct,
a pumping duct constructed to guide the thermal conditioning fluid from a pumping duct inlet to a pumping duct outlet, the pumping duct inlet being connected to the collecting duct outlet,
a pumping duct magnet system arranged along the pumping duct and configured to generate a magnetic field in at least a part of the pumping duct, and
a pump driver system configured to drive the collecting duct magnet system to generate a spatial repetition of collecting duct magnetic fields moving from the collecting duct inlet to the collecting duct outlet, and configured to drive the pumping duct magnet system to generate a spatial repetition of pumping duct magnetic fields moving from the pumping duct inlet to the pumping duct outlet.

19. The apparatus according to claim 18, wherein a diameter of the collecting duct exceeds a diameter of the pumping duct.

20. The apparatus according to claim 18, wherein a magnetic field strength of the pumping duct magnetic field exceeds a magnetic field strength of the collecting duct magnetic field.
